(19) United States
(12) Patent Application Publication
(10) Pub. No.: US 2003/0050064 A1
(43) Pub. Date: Mar. 13, 2003

(54) Handover in cellular radio systems

(75) Inventors: Robert J. Davies, Norley (GB); Andrew T. Yule, East Grinstead (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/210,543

(22) Filed: Aug. 1, 2002

(30) Foreign Application Priority Data
Sep. 8, 2001 (GB) 0119391.1

(51) Int. Cl. H04B 1/034; H04B 1/06; H05K 11/02; H04Q 7/20; H04B 7/00

(52) U.S. Cl. 455/441; 455/440; 455/525; 455/99; 455/345

(57) ABSTRACT

A cellular radio system comprises a radio coverage area formed by a plurality of cells (C1,C2), each cell having at least one primary station (PS1,PS2) including a radio transceiver for communicating with a secondary station (SS1,SS2) when in its cell. The or each secondary station is able to roam within the radio coverage area. In order to facilitate call handover the secondary station informs the infrastructure (PS1, PS2, 10) of its velocity and the infrastructure uses knowledge of the velocity to make a decision regarding handing over a call-in-progress from one cell to another cell. The velocity information may be provided by a GPS receiver (18) carried by a vehicle in which the secondary station is located and the information is relayed to the secondary station by way of a short range radio system. The secondary station uses the cellular system to forward this information to the infrastructure.

The present invention relates to handover in cellular radio systems, such as cellular telephone systems.

Handover in cellular telephone systems is not new per se. A basic concept is a network controller determining that the quality of a call between a mobile radio unit (or secondary station) and a base station (or primary station) located in a cell is deteriorating and conducting a search to determine which of the base stations in adjoining cells could sustain a better quality call with the mobile radio unit. Once the determination is made, the call-in-progress is transferred, or handed-over, to the next base station. Drawbacks to this basic concept are that prior to handover it is necessary to check the quality of signal propagation with a number of base stations having service areas in the vicinity of the cell in which the mobile radio unit is currently located, at handover it is necessary for there to be a free duplex voice channel for use by the call-in-progress and also details of the mobile radio unit have to be handed over which uses up system capacity.

If the cells are small, so-called micro- or pico- cells, then for a relatively fast moving mobile radio unit, handovers occur frequently. Consequently there is an on-going signal overhead which reduces the system capacity.

European Patent Specification EP-B1-0 369 535 discloses a method of handover in a microcellular radio system in which base stations in a cluster of cells surrounding the cell in which the mobile radio unit is currently present reserve a duplex voice channel in anticipation of handover to one of the base stations. In a refinement applicable to situations where a mobile radio unit is travelling along a predictable path, such as a railway line or a motorway not having an exit within a reasonable distance, the so-called cluster can be revamped to comprise a generally linearly arranged subset of adjacent cells covering the predictable path. The number of cells in the subset may be related to the speed of movement of the radio unit. In another refinement, the network controller or the base station builds up a call history of the mobile radio unit, and on determining that the mobile radio unit is apparently moving along a predictable path, instructs the formation of subsets of cells aligned with this path.

If the teachings of EP-B1-0 369 535 were applied to larger cells, a great deal of system capacity would have to be reserved in anticipation of handover.

U.S. Patent Specification No. 6,052,598 discloses that if approximate successive locations of a mobile radio unit can be determined then an estimate can be made of the speed and direction of travel of the mobile radio unit and this information can be used to predict when call handover to another cell is necessary and to which cell this will be, based on a data base in the network controller storing an electronic map of the entire network. Estimating the location of a mobile radio unit based on measuring signal strength values and relaying these values to a network controller by way of base stations will create an overhead of a lot of channel signalling which will be to the detriment of the system signalling capacity.

An object of the present invention is to effect handover of a call-in-progress in an effective manner.

According to one aspect of the present invention there is provided a method of handing over a call-in-progress in a cellular radio system, the system comprising a radio coverage area formed by a plurality of cells, each cell having at least one primary station including a radio transceiver, and at least one secondary station having a transceiver, the secondary station being able to roam within the radio coverage area, the method comprising the at least one secondary station providing the infrastructure with information relating to its velocity and the infrastructure using the velocity information to make a decision regarding handing over the call-in-progress from one cell to another cell.

According to a second aspect of the present invention there is provided a cellular radio system comprising infrastructure including a plurality of primary station transceivers providing a radio coverage area consisting of cells, at least one secondary station transceiver able to roam from cell to cell whilst participating in a call-in-progress, the at least one secondary station having means enabling it to transmit information relating to its velocity to the infrastructure, and the infrastructure having means for using the velocity information to make a decision regarding handing-over the call-in-progress from one cell to another cell.

According to a third aspect of the present invention there is provided a secondary station for use in a cellular radio system comprising infrastructure including a plurality of primary station transceivers providing a radio coverage area consisting of cells, the secondary station being able to roam from cell to cell whilst participating in a call-in-progress, wherein the secondary station has a transceiver for communicating with a selected primary station, and means enabling it to transmit information relating to its velocity to the infrastructure for use by the infrastructure in making a decision regarding handing-over the call-in-progress from one cell to another cell.

According to a fourth aspect of the present invention there is provided a vehicle comprising at least one radio beacon and means for providing information relating to the velocity of the vehicle and for supplying this information to the radio beacon. The vehicle may further comprise a secondary station for use in a cellular radio system comprising infrastructure including a plurality of primary station transceivers providing a radio coverage area consisting of cells, the secondary station being able to roam from cell to cell whilst participating in a call-in-progress, the secondary station having means for receiving the information from the radio beacon, a transceiver for communicating with a selected primary station, and means enabling it to forward the information relating to velocity to the infrastructure for use by the infrastructure in making a decision regarding handing-over the call-in-progress from one cell to another cell.

The method in accordance with the present invention uses knowledge of the vehicle's velocity (i.e. speed and direction) in making a decision about call handover. In practice the method requires only those secondary stations involved in a call-in-progress to forward velocity information to the infrastructure thus minimising the impact on the system capacity and insodoing reducing the number of dropped calls during the handover process.

In embodiments of the method in accordance with the present invention the secondary station is informed of its velocity, for example by a beacon mounted on a vehicle carrying the secondary station, the beacon receiving velocity information from say a GPS system or calculating velocity from speed information provided by an odometer carried by the vehicle, or a radio link between a trackside beacon and the vehicle, for example a train, in which the secondary station is being carried.

The system may comprise cells of different sizes, at least some of the smaller cells being located within larger cells or bridging the boundaries of larger cells. In operation the infrastructure takes into account velocity of the secondary station and cell size in making a decision to handover a call-in-progress.

In a refinement of the method in accordance with the present invention, the secondary station may inform the infrastructure of its location.

The infrastructure may use the information, that is velocity and/or location, relayed to it in order to predict which cell the secondary station will enter and reserve a radio channel in that cell.

The present invention will now be described, by way of example, with reference to the accompanying drawings, wherein;

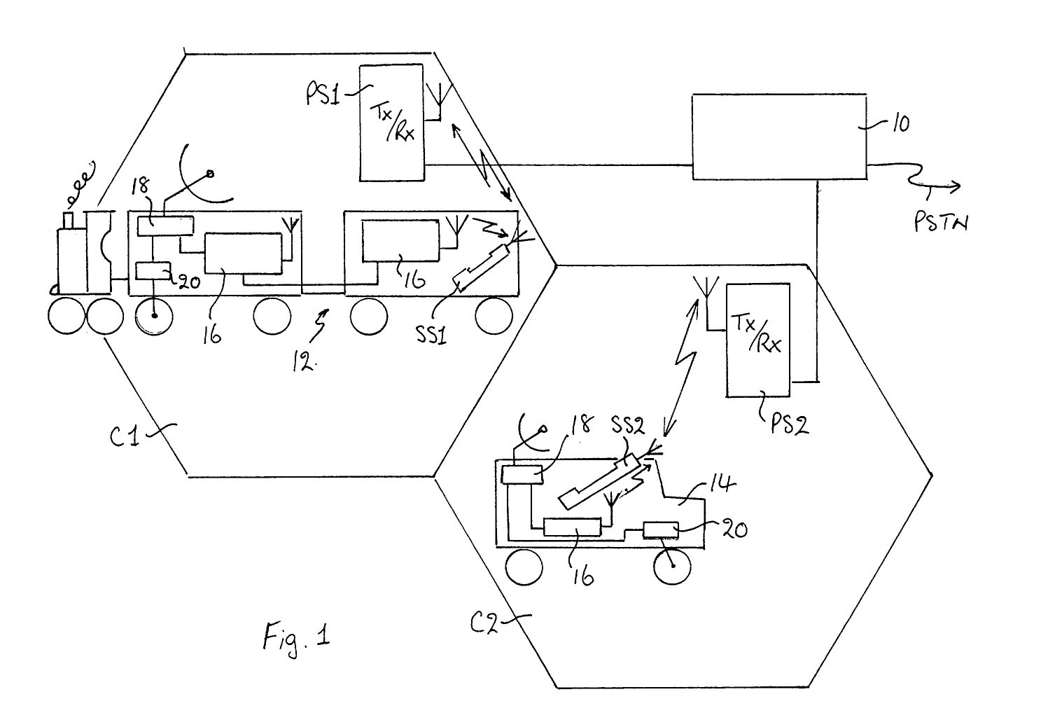

FIG. 1 is a block schematic diagram of a simplified example of a cellular radio system,

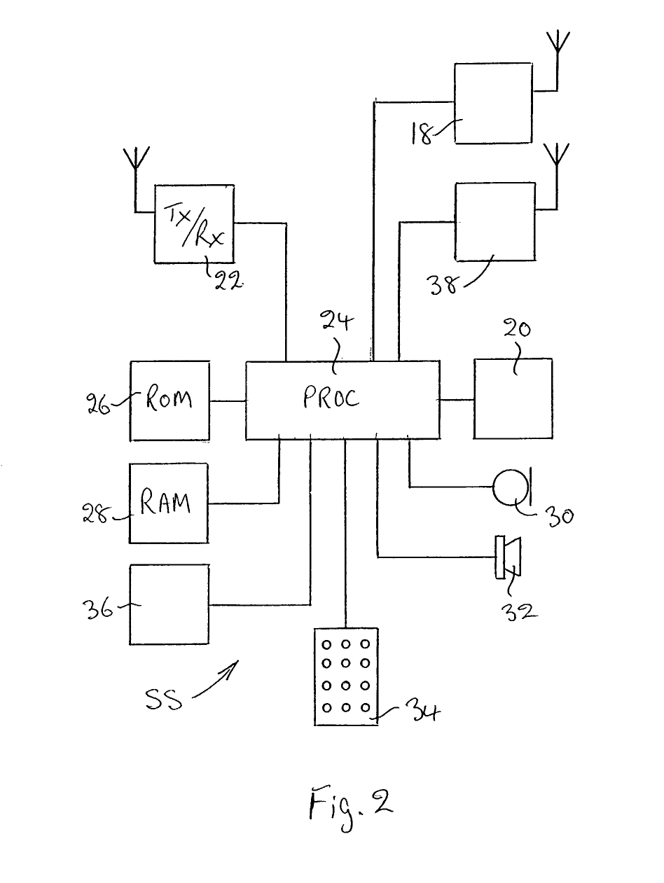

FIG. 2 is a block schematic diagram of a secondary station for use in the cellular radio system shown in FIG. 1, and

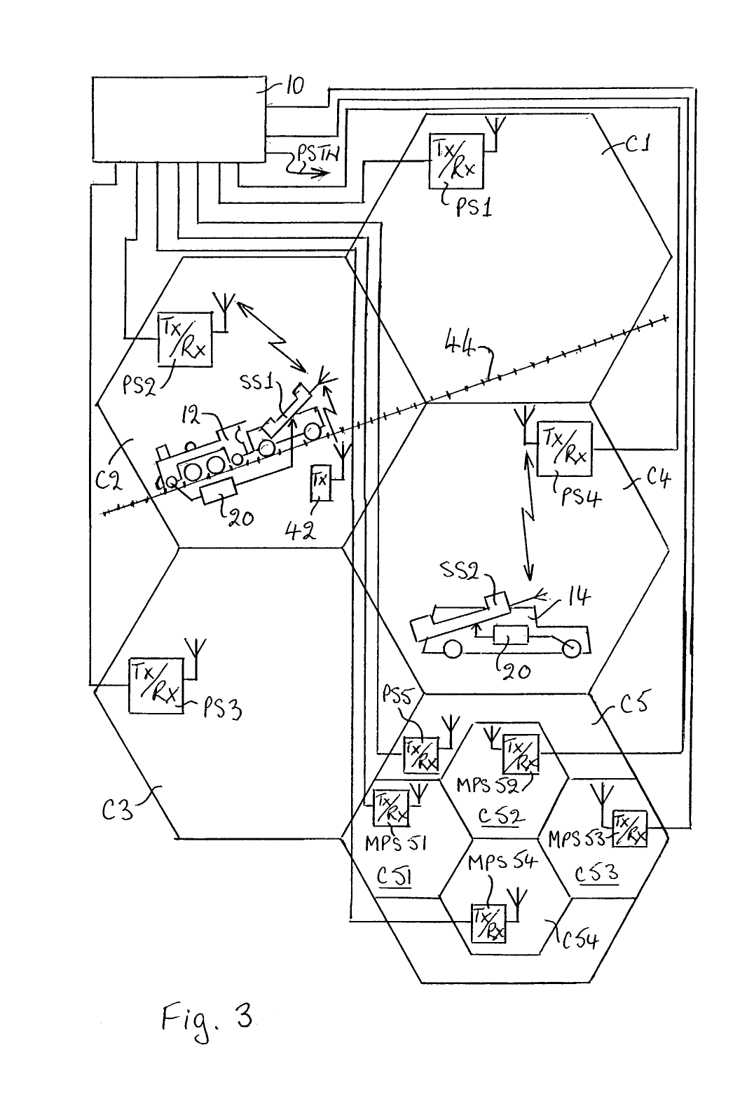

FIG. 3 is a block schematic diagram of other embodiments of a cellular radio system which can be used with, or as an alternative to, features shown in FIG. 1.

In the drawings the same reference numerals have been used to indicate corresponding features.

Referring to FIG. 1, the cellular radio system which for convenience of illustration is a cellular telephone system comprises a network controller 10 (sometimes termed a trunking switching controller) having landline or wideband radio links with a plurality of primary stations of which two PS1 and PS2 are shown and 2-way links to the public switched network PSTN. The network controller 10 is essentially a large computer which has storage for details of the users on the network and optionally a data base storing digitally a map of the network.

Each of the primary stations PS1, PS2 comprises at least one transceiver coupled to at least one antenna which may be a directional antenna. Each of the primary stations PS1, PS2 has a respective coverage area, termed a cell C1, C2, and their transmitters are so located and have their output powers so adjusted that the cells generally abut or partially overlap one another. For convenience of illustration the cells have been shown as regular hexagons but in reality topographical features, for example hills and tall buildings, and/or engineering features, such as directional antenna arrangements, influence the shape of a cell.

The system further comprises secondary stations SS1, SS2 which may be transportable, for example hand portable or semi-permanently mounted in a vehicle, or fixedly sited. The transportable secondary stations can be conveyed in many different ways including public transport, such as the secondary station SS1 on the train 12, or the secondary station SS2 in the car 14.

The basic operation of a cellular telephone network is well known. Calls are normally routed by way of the network controller 10. Calls can be between the PSTN and secondary stations or between secondary stations. The location of each active secondary station is known to the network controller 10 through a secondary station registration process. When a secondary station user is engaged in a call-in-progress and roams towards the boundary of its presently occupied cell, the signal quality deteriorates and it is necessary to handover the call-in-progress to the primary station of an adjoining cell. Generally the apparently seamless handover of a moving secondary station from one primary station to another is based only on measurement of comparative signal strength, that is, the signal from one primary station being stronger than that from another, and/or signal to interference ratios, that is, how strong is a signal from a given secondary station in comparison to other unwanted transmissions. A less effective method of call handover can have a significant impact on the overall system performance and capacity. For example, a handover process which is repeatedly passing a call back and forth between two or more primary stations wastes resources, whilst instigating a handover too slowly could result in an excess of dropped calls. The method in accordance with the present invention endeavours to mitigate these problems by using information about the velocity, that is speed and direction, of the handset involved with the call-in-progress to augment the other information which is used in making a hand-over decision. The infrastructure comprising the network controller 10 and the primary stations PS1,PS2 can then use this information when deciding whether a cell handover should take place and, if so, the identity of the new cell.

Velocity information can be provided by a secondary station in a variety of ways.

If one takes the example of the train 12, velocity information can be derived by a satellite positioning system receiver 18, for example GPS, and/or derived using an odometer 20 and supplied to a short range radio communication system, such as Bluetooth, Registered Trade Mark, which comprises a plurality of spatially separated beacons 16. The beacons 16 can relay a signal relating the train's current velocity throughout the train. This signal is picked-up by the secondary station SS1 and using the cellular telephone network it is forwarded to the network controller 10 by way of the secondary station SS1. The network controller 10 is able to estimate the train's location using its prestored map of the network and can predict the next cell into which the secondary station SS1 is likely to move.

In the case of the car 14, velocity information can be derived using an installed satellite positioning receiver 18 and/or an odometer 20. The receiver 18 is coupled to a short range radio communication beacon 16. Location information can also be derived by the receiver 18 and relayed to the network controller 10.

As an alternative for determining location the network controller may employ triangulation techniques well known in the art.

In a refinement to reduce the amount of signalling, threshold velocity control can be applied so that stationary and slow moving secondary stations either less frequently or do not report their velocities. The rate of reporting velocities to the network controller 10 may be made velocity dependent.

Referring to FIG. 2, the secondary station SS comprises a transceiver 22 for communicating with a primary station shown in FIG. 1. A processor 24 controls the operation of the secondary station in accordance with program software stored in a program ROM 26. The processor has inputs/outputs coupled to the transceiver 22, a random access memory (RAM) 28 which stores data and messages, a microphone 30, a loudspeaker 32, a keypad 34 and signal strength measuring means 36 which monitors the signal strength of a call-in-progress. Another transceiver 38 is provided to enable velocity/location information to be received by the secondary station and for this information to be relayed by the transceiver 22 to the network controller 10 (FIG. 1). The transceiver 38 may be capable of receiving velocity/location information from sources such as a beacon 16 (FIG. 1) by way of a low power radio link, for example Bluetooth, Registered Trade Mark. A satellite positioning system receiver 18 may be coupled to the processor 24. For the sake of completeness another input of the processor 24 is coupled to an odometer 20 which provides information about the speed of a vehicle carrying the secondary station. The processor 24 has software for deriving velocity information and relaying it together with signal strength information to the infrastructure for use in handing over a call-in-progress from one primary station to another.

The method in accordance with the present invention can be applied to any suitable cellular radio system and may give additional operating benefits. For example in the case of a UMTS system, the network controller 10 could use velocity information to facilitate successful soft handover. If soft handover is not possible because a channel is not available, then there is the possibility of greater time to evaluate channels for hard handover.

Referring to FIG. 3, the illustrated cellular radio system comprises a plurality of primary stations PS1 to PS5 and MPS51 to MPS54 and 2-way links to the public switched network PSTN.

Each of the primary stations PS1 to PS5 and MPS51 to MPS54 comprises at least one transceiver coupled to at least one antenna which may be a directional antenna. Each of the primary stations PS1 to PS5 and MPS51 to MPS4 has a respective coverage area, termed a cell C1 to C5 and C51 to C54, and the transmitters are so located and have their output powers so adjusted that the cells generally abut or partially overlap one another. For convenience of illustration the cells have been shown as regular hexagons but in reality topographical features, for example hills and tall buildings, and/or engineering features, such as directional antenna arrangements, influence the shape of a cell. The primary stations MPS51 to MPS54 are low power primary stations and define microcells C51 to C54 which are located within the cell C5. Microcells cater for slow moving secondary stations, such as those carried by persons on foot as opposed to for example on a train 12 or in a car 14. Thus when a secondary station enters cell C5, the network controller 10 has to decide whether to allocate a microcell C51 to C54 to the call in which case the call is routed to one of the primary statioms MPS51 to MPS54 or to route the call to the primary station MP5 which has the capability of covering the entire cell C5. The choice of locating low power primary stations in the cells C1 to C5 is determined by the architecture of the network.

Hand portable secondary stations can be transported in many different ways including public transport such as the secondary station SS1 on the train 12 or the secondary station SS2 in the car 14.

The basic operation of a cellular telephone network has been summarised with referenced to FIG. 1 and in the interests of brevity will not be repeated.

Velocity information can be provided by a secondary station in a variety of other ways besides using the short range radio beacons 16 (FIG. 1) carried in a vehicle.

If one takes the example of a vehicle such as the train 12, velocity information can be supplied by a beacon 42 arranged in close proximity to its path of movement which in this example is the railway track 44. Using a short range communication system such as Bluetooth, Registered Trade Mark, the beacon 42 can relay the train's current velocity and the beacon's identity (or location) to the secondary station SS1 which uses the cellular telephone network to relay the information to the network controller 10 by way of the primary station PS2. The network controller 10 is able to estimate the train's location using its prestored map of the network and can predict the next cell into which the secondary station SS1 is likely to move. If the speed of the secondary station is high, the network controller 10 can avoid allocating the call to small cells, such as the cells C51 to C54, that the user will pass through rapidly necessitating frequent handovers.

In variants of this embodiment, the speed may be determined from an odometer 20 coupled to a wheel of the train and this information can be combined with location information derived from the beacon 42 to enable velocity and position information to be forwarded by the secondary station to the network controller 10.

In the case of the car 14, velocity information can be derived using an odometer 20 which is coupled to the secondary station SS2. Location information can be derived by a GPS receiver built into the car or supplied by roadside beacons similar to the beacon 42.

As an alternative for determining location the network controller may employ triangulation techniques well known in the art.

In the present specification and claims the word “a” or “an” preceding an element does not exclude the presence of a plurality of such elements. Further, the word “comprising” does not exclude the presence of other elements or steps than those listed.

1. A method of handing over a call-in-progress in a cellular radio system, the system comprising a radio coverage area formed by a plurality of cells, each cell having at least one primary station including a radio transceiver, and at least one secondary station having a transceiver, the secondary station being able to roam within the radio coverage area, the method comprising the at least one secondary station providing the infrastructure with information relating to its velocity and the infrastructure using the velocity information to make a decision regarding handing over the call-in-progress from one cell to another cell.

2. A method as claimed in claim 1, characterised in that the at least one secondary station is provided with velocity information by way of a radio is beacon installed in a vehicle in which the at least one secondary station is being carried.

3. A method as claimed in claim 1, characterised in that the at least one secondary station is provided with velocity information by way of a radio beacon mounted adjacent to a path of movement of the at least one secondary station.

4. A method as claimed in any one of claims 1 to 3, characterised in that threshold velocity control is applied to the provision of velocity information by the at least one secondary station.

5. A method as claimed in any one of claims 1 to 3, characterised in that the provision of velocity information by the at least one secondary station is made at intervals of time which are velocity dependent.

6. A method as claimed in any one of claims 1 to 5, wherein the system comprises cells of different sizes, characterised in that the infrastructure takes into account cell size in making a decision to handover a call-in-progress.

7. A method as claimed in any one of claims 1 to 6, characterised in that the velocity information is used to effect a soft hand over of a call-in-progress.

8. A method as claimed in any one of claims 1 to 7, characterised by the secondary station providing the infrastructure with information relating to its location.

9. A method as claimed in any one of claims 1 to 8, characterised by the infrastructure using information provided by the secondary station to predict which cell the secondary station will enter and reserving a radio channel in that cell.

10. A cellular radio system comprising infrastructure including a plurality of primary station transceivers providing a radio coverage area consisting of cells, at least one secondary station transceiver able to roam from cell to cell whilst participating in a call-in-progress, the at least one secondary station having means enabling it to transmit information relating to its velocity to the infrastructure, and the infrastructure having means for using the velocity information to make a decision regarding handing-over the call-in-progress from one cell to another cell.

11. A system as claimed in claim 10, characterised by at least one beacon for sending velocity information to the secondary station.

12. A system as claimed in claim 10 or 11, characterised by means for providing the at least one secondary station with information for use by the infrastructure to determine the location of the at least one secondary station.

13. A secondary station for use in a cellular radio system comprising infrastructure including a plurality of primary station transceivers providing a radio coverage area consisting of cells, the secondary station being able to roam from cell to cell whilst participating a call-in-progress, wherein the secondary station has a transceiver for communicating with a selected primary station, and means enabling it to transmit information relating to its velocity to the infrastructure for use by the infrastructure in making a decision regarding handing-over the call-in-progress from one cell to another cell.

14. A secondary station as claimed in claim 13, characterised by means for receiving velocity information from a radio beacon.

15. A secondary station as claimed in claim 13 or 14, characterised by means for receiving location information relating to the secondary station and for relaying the location information to the infrastructure.

16. A vehicle comprising at least one radio beacon and means for providing information relating to the velocity of the vehicle and for supplying this information to the radio beacon for transmission.

17. A vehicle as claimed in claim 16, further comprising a secondary station for use in a cellular radio system comprising infrastructure including a plurality of primary station transceivers providing a radio coverage area consisting of cells, the secondary station being -able to roam from cell to cell whilst participating in a call-in-progress, the secondary station having means for receiving the information from the radio beacon, a transceiver for communicating with a selected primary station, and means enabling it to forward the information relating to velocity to the infrastructure for use by the infrastructure in making a decision regarding handing-over the call-in-progress from one cell to another cell.
